(19) United States
(12) Patent Application Publication
(10) Pub. No.: US 2023/0257641 A1
(43) Pub. Date: Aug. 17, 2023

(54) THERMALLY CONDUCTIVE PHASE-CHANGE COMPOSITION, METHODS OF MANUFACTURE THEREOF, AND ARTICLES INCLUDING THE COMPOSITION

(71) Applicant: ROGERS CORPORATION, Chandler, AZ (US)

(72) Inventors: Kuitian Tan, Westborough, MA (US); David William Baker, Woodstock, CT (US); Ian Smith, Dayville, CT (US)

(21) Appl. No.: 18/016,219

(22) PCT Filed: Jul. 15, 2021
(86) PCT No.: PCT/US2021/041794

§ 371 Date: Jan. 13, 2023

Related U.S. Application Data
(60) Provisional application No. 63/052,575, filed on Jul. 16, 2020.

(51) Int. Cl. C09K 5/06; C08K 13/04; C08J 3/21; H05K 7/20

(52) U.S. Cl. CPC C09K 5/063; C08J 3/212; C08K 13/04; H05K 7/2039; C08K 7/06

(57) ABSTRACT

A thermally conductive phase-change composition includes a mixture of 5 to 25 weight percent thermoplastic polymer; 20 to 45 weight percent phase-change material; and 30 to 65 weight percent thermally conductive particles, wherein weight percent is based on the total weight of the composition and totals 100 weight percent, and wherein thermal conductivity of the composition is at least 3.0 W/m-K at a temperature below the transition temperature of the phase change material and thermal conductivity of the composition is at least 2.0 W/m-K at a temperature above the transition temperature of the phase change material, wherein thermal conductivity is determined in accordance with ASTM E1530. The phase-change compositions are reworkable and can be easily and cleanly removed from a device for maintenance and repair and repositioned without causing damage to the device.

### CROSS REFERENCE TO RELATED APPLICATIONS

This application claims the benefit of U.S. Application No. 63/052575, filed on Jul. 16, 2020, which is incorporated herein by reference in its entirety.

### BACKGROUND

This disclosure relates to thermally conductive phase-change compositions, methods of manufacture thereof, and articles including the compositions.

Thermal management is desirable in a wide range of devices, including batteries, devices containing light-emitting diodes (LEDs), and devices containing circuits. For example, circuit designs for electronic devices such as televisions, radios, computers, medical instruments, business machines, and communications equipment have become increasingly smaller and thinner. The increasing power of such electronic components has resulted in increasing heat generation. Moreover, smaller electronic components are being densely packed into ever smaller spaces, resulting in more intense heat generation.

At the same time, electronic devices can be very sensitive to over-heating, negatively influencing both lifetime, reliability of the parts, and user experience and safety. Temperature-sensitive elements in electronic devices may need to be maintained within a prescribed operating temperature in order to avoid significant performance degradation or even system failure. Consequently, manufacturers are continuing to face the challenge of dissipating heat generated in electronic devices, i.e., thermal management. Moreover, the internal design of electronic devices may include irregularly shaped components and cavities that present a significant challenge for known thermal management approaches.

Accordingly, there remains a need for new compositions for thermal management in various devices, and particularly in electronic devices. It would be an advantage if the compositions were effective for introduction into small or thin devices or devices with irregularly shaped cavities and if the compositions were reworkable. It would be an additional advantage for the compositions to have a reversible, tunable thermal conductivity and multiple mechanisms for thermal regulation of a device

### BRIEF SUMMARY

A thermally conductive phase-change composition includes a combination comprising 5 to 25 weight percent of a thermoplastic polymer; 20 to 45 weight percent of a phase-change material; and 30 to 65 weight percent of thermally conductive particles, wherein weight percent is based on the total weight of the composition and totals 100 weight percent, and wherein thermal conductivity of the composition is at least 3.0 W/m-K at a temperature below a transition temperature of the phase-change material and thermal conductivity of the composition is at least 2.0 W/m-K at a temperature above the transition temperature of the phase-change material, wherein thermal conductivity is determined in accordance with ASTM E1530.

A method of manufacturing the phase-change composition includes combining to obtain a phase-change composition: the thermoplastic polymer, optionally a solvent, the phase-change material, and the thermally conductive particles; and optionally removing the solvent.

Also disclosed are articles including the phase-change composition.

A method of manufacturing an article includes subjecting the phase-change composition to a temperature and/or pressure effective to introduce the phase-change composition into or onto a desired location of an article.

The above described and other features are exemplified by the following detailed description.

### DETAILED DESCRIPTION

Disclosed herein are novel phase-change compositions having a high heat of fusion at the phase transition temperature and a high thermal conductivity. The phase-change compositions include a mixture of a thermoplastic polymer, a phase-change material, thermally conductive particles, and optionally other components. These phase-change compositions are especially suitable for providing excellent thermal protection to a wide variety of devices, and in particular electronic devices. The phase-change compositions advantageously have a reversible, tunable thermal conductivity and multiple mechanisms for thermal regulation of a device. At elevated temperature, the thermally conductive particles function by conducting the heat to a cooler surface or environment. Phase change materials function by absorbing and storing the heat above the onset of the phase transition temperature and only release the heat to a cooler surface or environment when the device temperature drops below the phase transition temperatures. The differences in the thermal regulation mechanisms of the thermally conductive filler particles and the phase change material offer additional benefits not only for device performance, but also for user safety. If a user is hand holding or touching an electronic device, the heat generated by the device may cause an unpleasant experience, or even burn the user’s skin. At a temperature below the onset of the phase transition, unwanted heat can be conducted away from sensitive electronic components solely by the thermally conductive particles; while at a temperature at or above the onset of the phase transition, even though the thermal conductivity of the thermally conductive filler particles is reduced compared to the thermal conductivity below the phase transition temperature, more heat can be dissipated by a combination of thermal conduction through the thermally conductive filler particles and the heat of fusion of the phase change material. More importantly, the reduced thermal conductivity of the phase-change compositions above the phase transition temperature slows down heat dissipation to the cooler device surface by the thermally conductive particles, thus reducing the chance of causing an unpleasant user experience, or even a skin burn of a user holding or touching the device. During the cooling process, thermally conductive fillers can facilitate faster cooling than using only phase change materials. In summary, the synergism of the combination of thermally conductive filler particles and phase change materials in the disclosed phase-change compositions offers better thermal management of devices, such as handheld electronic devices, during the heating process, at the peak heating temperature, and during the cooling process.

The phase-change compositions are shape stable at ambient temperature for ease of downstream handling and processing. At elevated temperature, they are conformable and become pliable or flowable under heat and/or pressure. The phase-change compositions can therefore be easily introduced into a desired location of any shape. Further, the effect of temperature and/or pressure on the level of conformability and fluidity of the phase-change compositions is reversible. As a result, the phase-change compositions are reworkable and can be easily and cleanly removed from a device for maintenance and repair and repositioned without causing damage to the device, in contrast to use of non-reworkable compositions such as highly crosslinked or thermoset systems.

The internal design of electronic devices can include irregularly shaped cavities that can be difficult to fill completely with solid phase-change materials to maximize heat absorption capacity. The phase-change compositions disclosed herein have the benefit that when subjected to temperature and/or pressure the phase-change compositions flow and can be readily inserted into irregularly shaped cavities in such devices in order to maximize heat absorption capacity. After cooling or removal of the pressure, the phase-change compositions do not flow and therefore do not leak out of the device at the operating temperature of the device (e.g., less than 100° C. or less than 50° C.).

The phase-change composition includes a combination in admixture of a thermoplastic polymer, a phase-change material, and thermally conductive particles. Optionally, the phase-change composition further comprises 0.5 to 5 weight percent of carbon fiber, an additive composition, or a combination thereof. The phase-change material and the thermoplastic polymer composition are selected to have good compatibility, permitting the phase-change material to be present in a miscible blend with the thermoplastic polymer composition. The phase-change composition does not exhibit appreciable flow at room temperature (25° C.) and standard pressure.

Careful selection of the thermoplastic polymer composition, the phase-change material, the thermally conductive particles, optional carbon fiber, and optional additive composition permits tuning the properties of the phase-change compositions.

The phase-change composition has a transition temperature, determined by differential scanning calorimetry according to ASTM D3418, of at least 0° C., at least 5° C., at least 10° C., at least 15° C., at least 20° C., at least 25° C., at least 30° C., at least 35° C., at least 40° C., or at least 45° C. and up to 50° C., up to 55° C., up to 60° C., up to 65° C., up to 70° C., up to 75° C., up to 80° C., up to 85° C., up to 90° C., or up to 95° C. Exemplary ranges of the transition temperature include 0 to 95° C., 5 to 70° C., 20 to 65° C., 25 to 60° C., 25 to 70° C., 30 to 50° C., 35 to 45° C., 35 to 50° C., 30 to 95° C., or 35 to 95° C. In some embodiments, the phase-change composition has a heat of fusion, determined by differential scanning calorimetry according to ASTM D3418, of at least 80 Joules/gram (J/g), at least 100 J/g, at least 120 J/g, at least 140 J/g, at least 150 J/g, at least 180 J/g, at least 200 J/g, preferably at least 120 J/g, more preferably at least 140 J/g.

The phase-change composition has a reversible, tunable thermal conductivity. At a temperature below the transition temperature of the phase-change composition, thermal conductivity of the phase-change composition is at least 3.0 W/m-K, at least 3.5 W/m-K, at least 4.0 W/m-K, at least 5.0 W/m-K, or at least 10 W/m-K and at a temperature above the transition temperature of the phase-change composition thermal conductivity of the composition is at least 2.0 W/m-K, at least 3.0 W/m-K, at least 3.5 W/m-K, at least 4.0 W/m-K, or at least 4.5W/m-K. Thermal conductivity is determined in accordance with ASTM E1530.

A phase-change material (PCM) is a substance with a high heat of fusion, and that is capable of absorbing and releasing high amounts of latent heat during a phase transition, such as melting and solidification, respectively. During the phase change, the temperature of the phase-change material remains nearly constant. The phase-change material inhibits or stops the flow of thermal energy through the material during the time the phase-change material is absorbing or releasing heat, typically during the material’s change of phase. In some instances, a phase-change material can inhibit heat transfer during a period of time when the phase-change material is absorbing or releasing heat, typically as the phase-change material undergoes a transition between two states. This action is typically transient and will occur until a latent heat of the phase-change material is absorbed or released during a heating or cooling process. Heat can be stored or removed from a phase-change material, and the phase-change material typically can be effectively recharged by a source of heat or cold.

Phase-change materials thus have a characteristic transition temperature. The term “transition temperature or “phase-change temperature” refers to an approximate temperature at which a material undergoes a transition between two states. In some embodiments, e.g. for a commercial paraffin wax of mixed composition, the transition “temperature” can be a temperature range over which the phase transition occurs.

In principle, it is possible to use phase-change materials having a phase-change temperature of -100 to 150° C. in the phase-change compositions. For use in LED and electronic components, in particular, the phase-change material incorporated into the phase-change compositions can have a phase-change temperature of 0 to 115°C, 10 to 105° C., 20 to 100° C., or 30 to 95° C. In an embodiment, the phase-change material has a melting temperature of at least 0° C., at least 5° C., at least 10° C., at least 15° C., at least 20° C., at least 25° C., at least 30° C., at least 35° C., at least 40° C., or at least 45° C. and up to 50° C., up to 55° C., up to 60° C., up to 65° C., up to 70° C., up to 75° C., up to 80° C., up to 85° C., up to 90° C., or up to 95° C. Exemplary ranges of the melting temperature include 25 to 70° C., 25 to 105° C., or 28 to 60° C., or 35 to 50° C., 45 to 85° C., or 60 to 80° C., or 80 to 100° C.

The selection of a phase-change material typically depends upon the transition temperature that is desired for a particular application that is going to include the phase-change material. For example, a phase-change material having a transition temperature near normal body temperature or around 37° C. can be desirable for electronics applications to prevent user injury and protect overheating components. The phase-change material can have a transition temperature in the range of -5 to 150° C., or 0 to 90° C., or 25 to 70° C., 30 to 70° C., or 35 to 50° C.

In other applications, for example a battery for an electric vehicle, a phase-change temperature of 65° C. or higher can be desirable. A phase-change material for such applications can have a transition temperature in the range of 45 to 85° C., or 60 to 80° C., or 80 to 100° C.

The transition temperature can be expanded or narrowed by modifying the purity of the phase-change material, molecular structure, blending of phase-change materials, or any combination thereof. By selecting two or more different phase-change materials and forming a mixture, the temperature stabilizing range of the phase-change material can be adjusted for any desired application. A temperature stabilizing range can include a specific transition temperature or a range of transition temperatures. The resulting mixture can exhibit two or more different transition temperatures or a single modified transition temperature when incorporated in the phase-change compositions described herein.

In some embodiments, it can be advantageous to have multiple or broad transition temperatures. If a single narrow transition temperature is used, this can cause thermal/energy buildup before the transition temperature is reached. Once the transition temperature is reached, then energy will be absorbed until the latent energy is consumed and the temperature will then continue to increase. Broad or multiple transition temperatures allow for temperature regulation and thermal absorption as soon the temperature starts to increase, thereby alleviating any thermal/energy buildup. Multiple or broad transition temperatures can also more efficiently help conduct heat away from a component by overlapping or staggering thermal absorptions. For instance, for a composition containing a first phase-change material (PCM1) which absorbs at 35 to 40° C. and a second phase-change material (PCM2) which absorbs at 38 to 45° C., PCM1 will start absorbing and controlling temperature until a majority of the latent heat is used, at which time PCM2 will start to absorb and conduct energy from PCM1 thereby rejuvenating PCM1 and allowing it to keep functioning.

The selection of the phase-change material can depend on the latent heat of the phase-change material. A latent heat of the phase-change material typically correlates with its ability to absorb and release energy/heat or modify the heat transfer properties of the article. In some instances, the phase-change material can have a latent heat of fusion that is at least 20 J/g, such as at least 40 J/g, at least 50 J/g, at least 70 J/g, at least 80 J/g, at least 90 J/g, at least 100 J/g, at least 120 J/g, at least 140 J/g, at least 150 J/g, at least 170 J/g, at least 180 J/g, at least 190 J/g, at least 200 J/g, or at least 220 J/g. Thus, for example, the phase-change material can have a latent heat of fusion of 20 J/g to 400 J/g, such as 80 J/g to 400 J/g, or 100 J/g to 400 J/g, or 150 J/g to 400 J/g, or 170 J/g to 400 J/g, or 190 J/g to 400 J/g.

Phase-change materials that can be used include various organic and inorganic substances. Examples of phase-change materials include hydrocarbons (e.g., straight-chain alkanes or paraffinic hydrocarbons, branched-chain alkanes, unsaturated hydrocarbons, halogenated hydrocarbons, and alicyclic hydrocarbons), silicone wax, alkanes, alkenes, alkynes, arenes, hydrated salts (e.g., calcium chloride hexahydrate, calcium bromide hexahydrate, magnesium nitrate hexahydrate, lithium nitrate trihydrate, potassium fluoride tetrahydrate, ammonium alum, magnesium chloride hexahydrate, sodium carbonate decahydrate, disodium phosphate dodecahydrate, sodium sulfate decahydrate, and sodium acetate trihydrate), waxes, oils, water, saturated and unsaturated fatty acids for example, caproic acid, caprylic acid, lauric acid, myristic acid, palmitic acid, stearic acid, arachidic acid, behenic acid, lignoceric acid cerotic acid, and the like), fatty acid esters (for example, fatty acid C₁-C₄ alkyl esters, such as methyl caprylate, methyl caprate, methyl laurate, methyl myristate, methyl palmitate, methyl stearate, methyl arachidate, methyl behenate, methyl lignocerate, and the like), fatty alcohols (for example, capryl alcohol, lauryl alcohol, myristyl alcohol, cetyl alcohol, stearyl alcohol, arachidyl alcohol, behenyl alcohol, lignoceryl alcohol, ceryl alcohol, montanyl alcohol, myricyl alcohol, and geddyl alcohol, and the like), dibasic acids, dibasic esters, 1-halides, primary alcohols, secondary alcohols, tertiary alcohols, aromatic compounds, clathrates, semi-clathrates, gas clathrates, anhydrides (e.g., stearic anhydride), ethylene carbonate, methyl esters, polyhydric alcohols (e.g., 2,2-dimethyl-1,3-propanediol, 2-hydroxymethyl-2-methyl-1,3-propanediol, ethylene glycol, polyethylene glycol, pentaerythritol, dipentaerythritol, pentaglycerine, tetramethylol ethane, neopentyl glycol, tetramethylol propane, 2-amino-2-methyl-1,3-propanediol, monoaminopentaerythritol, diaminopentaerythritol, and tris(hydroxymethyl)acetic acid), sugar alcohols (erythritol, D-mannitol, galactitol, xylitol, D-sorbitol), polymers (e.g., polyethylene, polyethylene glycol, polyethylene oxide, polypropylene, polypropylene glycol, polytetramethylene glycol, polypropylene malonate, polyneopentyl glycol sebacate, polypentane glutarate, polyvinyl myristate, polyvinyl stearate, polyvinyl laurate, polyhexadecyl methacrylate, polyoctadecyl methacrylate, polyesters produced by polycondensation of glycols (or their derivatives) with diacids (or their derivatives), and copolymers, such as polyacrylate or poly(meth)acrylate with alkyl hydrocarbon side chain or with polyethylene glycol side chain and copolymers including polyethylene, polyethylene glycol, polyethylene oxide, polypropylene, polypropylene glycol, or polytetramethylene glycol), metals, and mixtures thereof. Various vegetable oils can be used, for example soybean oils, palm oils, or the like. Such oils can be purified or otherwise treated to render them suitable for use as phase-change materials. In an embodiment a phase-change material used in the phase-change composition is an organic substance.

Paraffinic phase-change materials can be a paraffinic hydrocarbon, that is, a hydrocarbon represented by the formula CₙHₙ₊₂, where n can range from 10 to 44 carbon atoms. The melting point and heat of fusion of a homologous series of paraffin hydrocarbons is directly related to the number of carbon atoms.

Similarly, the melting point of a fatty acid depends on the chain length.

In an embodiment, the phase-change material comprises a paraffinic hydrocarbon, a fatty acid, or a fatty acid ester having 15 to 44 carbon atoms, 18 to 35 carbon atoms, or 18 to 28 carbon atoms. The phase-change material can be a single paraffinic hydrocarbon, fatty acid, or fatty acid ester, or a mixture of hydrocarbons, fatty acids, and/or fatty acid esters. The phase-change material can be a vegetable oil. In a preferred embodiment the phase-change material has a melting temperature of 5 to 70° C., 25 to 65° C., 35 to 60° C., or 30 to 50° C.

The heat of fusion of the phase-change material, determined by differential scanning calorimetry according to ASTM D3418, can be greater than 120 Joules/gram, preferably greater than 180 Joules per gram, more preferably greater than 200 Joules/gram

The amount of the phase-change material depends on the type of material used, the desired phase change temperature, the type of thermoplastic polymer used, and like considerations, but is selected to provide a miscible blend of the phase-change material and the thermoplastic polymer after mixing. The amount of the phase-change material can be 20 to 45 weight percent, or 20 to 40 weight percent of the total weight of the phase-change composition, provided that a miscible blend of the phase-change material and the thermoplastic polymer is formed after mixing. The phase-change material can be unencapsulated (“raw”), encapsulated, or a combination thereof.

The phase-change composition further comprises a thermoplastic polymer composition. As used herein, “polymer” includes oligomers, ionomers, dendrimers, homopolymers, and copolymers (such as graft copolymers, random copolymers, block copolymers (e.g., star block copolymers, random copolymers, and the like. The thermoplastic polymer composition can be a single polymer or a combination of polymers. The combination of polymers can be, for example, a blend of two or more polymers having different chemical compositions, different weight average molecular weights, or a combination of the foregoing. Careful selection of the polymer or of the combination of polymers allows for tuning of the properties of the phase-change compositions.

The type and amount of thermoplastic polymer composition is selected to have good compatibility with the phase-change material, in order to form a miscible blend of the thermoplastic polymer composition and the phase-change material. If a combination of two or more polymers is used, the polymers are preferably miscible, or are miscible when combined with the phase-change material.

The polymer can be present in the thermally conductive phase-change composition in an amount of 5 to 25 weight percent, 8 to 22 weight percent, or 10 to 20 weight percent, the weight percents being based on the total weight of the phase-change composition.

In an embodiment, the thermoplastic polymer composition has low polarity. Low polarity of the thermoplastic polymer composition enables compatibility with a phase-change material of a non-polar nature.

One parameter that can be used to assess compatibility of the polymer composition with the unencapsulated phase-change material is the “solubility parameter” (δ) of the polymer composition and the phase-change material. Solubility parameters can be determined by any known method in the art or obtained for many polymers and phase-change materials from published tables. The polymer composition and phase-change material generally have similar solubility parameters to form a miscible blend. The solubility parameter (δ) of the polymer composition can be within ±1, or ±0.9, or ± 0.8, or ±0.7, or ±0.6, or ±0.5, or ±0.4, or ±0.3 of the solubility parameter of the unencapsulated phase-change material.

A wide variety of thermoplastic polymers can be used, alone or in combination, in the thermoplastic polymer composition depending on the phase-change material and other desired characteristics of the phase-change composition. Exemplary polymers that are generally considered thermoplastic include cyclic olefin polymers (including polynorbornenes and copolymers containing norbornenyl units, for example copolymers of a cyclic polymer such as norbornene and an acyclic olefin such as ethylene or propylene), fluoropolymers (e.g., polyvinyl fluoride (PVF), polyvinylidene fluoride (PVDF), fluorinated ethylene-propylene (FEP), polytetrafluoroethylene (PTFE), poly(ethylene-tetrafluoroethylene (PETFE), perfluoroalkoxy (PFA)), polyacetals (e.g., polyoxyethylene and polyoxymethylene), poly(C₁₋₆ alkyl)acrylates, polyacrylamides (including unsubstituted and mono-N- and di-N-(C₁₋₈ alkyl)acrylamides), polyacrylonitriles, polyamides (e.g., aliphatic polyamides, polyphthalamides, and polyaramides), polyamideimides, polyanhydrides, polyarylene ethers (e.g., polyphenylene ethers), polyarylene ether ketones (e.g., polyether ether ketones (PEEK) and polyether ketone ketones (PEKK)), polyarylene ketones, polyarylene sulfides (e.g., polyphenylene sulfides (PPS)), polyarylene sulfones (e.g., polyethersulfones (PES), polyphenylene sulfones (PPS), and the like), polybenzothiazoles, polybenzoxazoles, polybenzimidazoles, polycarbonates (including homopolycarbonates and polycarbonate copolymers such as polycarbonate-siloxanes, polycarbonate-esters, and polycarbonate-ester-siloxanes), polyesters (e.g., polyethylene terephthalates, polybutylene terephthalates, polyarylates, and polyester copolymers such as polyester-ethers), polyetherimides (including copolymers such as polyetherimide-siloxane copolymers), polyimides (including copolymers such as polyimide-siloxane copolymers), poly(C₁₋₆ alkyl)methacrylates, polymethacrylamides (including unsubstituted and mono-N- and di-N-(C₁₋₈ alkyl)acrylamides), polyolefins (e.g., polyethylenes, polypropylenes, and their halogenated derivatives (such as polytetrafluoroethylenes), and their copolymers, for example ethylene-alpha-olefin copolymers, poly(ethylene-vinyl acetate), polyoxadiazoles, polyoxymethylenes, polyphthalides, polysilazanes, polysiloxanes (silicones), polystyrenes (including copolymers such as acrylonitrile-butadiene-styrene (ABS) and methyl methacrylate-butadiene-styrene (MBS)), polysulfides, polysulfonamides, polysulfonates, polysulfones, polythioesters, polytriazines, polyureas, polyurethanes, vinyl polymers (including polyvinyl alcohols, polyvinyl esters, polyvinyl ethers, polyvinyl halides (e.g, polyvinyl fluoride), polyvinyl ketones, polyvinyl nitriles, polyvinyl thioethers, and polyvinylidene fluorides), or the like. A combination comprising at least one of the foregoing polymers can be used.

A preferred type of polymer is an elastomer, which can be optionally crosslinked. In some embodiments, use of a crosslinked (i.e., cured) elastomer provides lower flow of the phase-change compositions at higher temperatures. Suitable elastomers can be elastomeric random, grafted, or block copolymers. Examples include natural rubber/isoprene, butyl rubber, polydicyclopentadiene rubber, fluoroelastomers, ethylene-propylene rubber (EPR), ethylene-butene rubber, ethylene-propylene-diene monomer rubber (EPDM, or ethylene propylene diene terpolymer), acrylate rubbers, nitrile rubber, hydrogenated nitrile rubber (HNBR), silicone elastomers, styrene-butadiene-styrene (SBS), styrene-butadiene rubber (SBR), styrene-(ethylene-butene)-styrene (SEBS), acrylonitrile-butadiene-styrene (ABS), acrylonitrile-ethylene-propylene-diene-styrene (AES), styrene-isoprene-styrene (SIS), styrene-(ethylene-propylene)-styrene (SEPS), methyl methacrylate-butadiene-styrene (MBS), high rubber graft (HRG), polyurethane, silicone, acrylate and the like.

Elastomeric block copolymers comprise a block (A) derived from an alkenyl aromatic compound and a block (B) derived from a conjugated diene. The arrangement of blocks (A) and (B) include linear and graft structures, including radial tetrablock structures having branched chains. Examples of linear structures include diblock (A-B), triblock (A-B-A or B-A-B), tetrablock (A-B-A-B), and pentablock (A-B-A-B-A or B-A-B-A-B) structures as well as linear structures containing 6 or more blocks in total of A and B. Specific block copolymers include diblock, triblock, and tetrablock structures, and specifically the A-B diblock and A-B-A triblock structures. In some embodiments, the elastomer is a styrenic block copolymer (SBC) consisting of polystyrene blocks and rubber blocks. The rubber blocks can be polybutadiene, polyisoprene, their hydrogenated equivalents, or a combination thereof. Examples of styrenic block copolymers include styrene-butadiene block copolymers, e.g. KRATON D SBS polymers (Kraton Performance Polymers, Inc.); styrene-ethylene/propylene block copolymers, e.g., KRATON G SEPS (Kraton Performance Polymers, Inc.) or styrene-ethylene/butadiene block copolymers, e.g., KRATON G SEBS (Kraton Performance Polymers, Inc.); and styrene-isoprene block copolymers, e.g., KRATON D SIS polymers (Kraton Performance Polymers, Inc.). In certain embodiments, the polymer is a styrene-ethylene-butadiene-styrene block copolymer with 10-25% polystyrene, e.g., KRATON G 1642, G 1657, or a combination thereof. In certain embodiments, the polymer is KRATON G SEBS or SEPS, a styrene-butadiene block copolymer, polybutadiene, EPDM, natural rubber, butyl rubber, cyclic olefin copolymer, polydicyclopentadiene rubber, or a combination comprising one or more of the foregoing.

The phase-change composition further comprises thermally conductive particles. The thermally conductive particles can comprise irregularly shaped particles, spherical particles, flakes, fibers, rod-shaped particles, needle-shaped particles, or a combination thereof. The particles can be solid, porous, or hollow. The thermally conductive particles can comprise, for example, boron nitride, silica, alumina, zinc oxide, magnesium oxide, carbon fibers, graphite, aluminum nitride, and the like, and combinations thereof. Preferably the thermally conductive particles are boron nitride particles or carbon fibers. The average size of the thermally conductive particles depends on the particle shape, the type of material and like considerations, and is selected to provide the desired characteristics to the phase-change composition. For example, the thermally conductive particles, when spherically or irregularly shaped, can have an average particle size of 0.1 to 1000 micrometers (µm), of 1 to 100 µm, or 5 to 80 µm. The average particle size is a value based on volume obtained by a particle size distribution measurement method in a laser scattering method. For example, the average particle size is obtained by measuring a D50 value with a laser scattering particle size analyzer can have a range of sizes. For thermally conductive particles in needle shapes or plate shapes, the maximum length of each of the thermally conductive particles is 0.1 to 1000 µm, or 1 to 100 µm, or 5 to 45 µm. When the maximum length thereof is above 1000 µm, the thermally conductive particles can aggregate too easily with each other and the handling thereof becomes difficult. In addition, the aspect ratio (in the case of a needle-shaped crystal, expressed by the length of the long axis/the length of the short axis or the length of the long axis/the thickness and in the case of a plate-shaped crystal, expressed by the diagonal length/the thickness or the length of the long side/the thickness) thereof is 1 to 10000, or 1 to 1000.

The amount of the thermally conductive particles depends on the type of material used, the desired thermal conductivity of the final composition, and like considerations. The amount of the thermally conductive particles can be 30 to 65 weight percent, or 35 to 60 weight percent, each based on the total weight of the phase-change composition.

The phase-change composition further optionally comprises carbon fibers. The amount and type of carbon fiber are selected to improve the mechanical strength and reduce brittleness of the phase-change composition. When included in the phase-change composition, the carbon fiber is present at 0.5 to 5 weight percent, or 1 to 2 weight percent, based on the total weight of the phase-change composition. In some embodiments, the carbon fibers are pitch-based carbon fibers. Exemplary pitch-based carbon fibers include those available from Nippon Graphite Fiber Corporation (Japan). Average length of the fibers can be 10 micrometers to 6 millimeters, 50 to 200 micrometers, 1 to 3 millimeters, preferably 50 to 150 micrometers or 1 millimeter.

The phase-change compositions can consist, or consist essentially of, the combination of the phase-change material, the thermoplastic polymer composition, and the thermally conductive particles, in the amounts described above. Alternatively, the phase-change compositions can further comprise other components, such as a particulate filler and other as additives known in the art. Such additional components are selected so as to not significantly adversely affect the desired properties of the phase-change compositions, in particular the recited heat of fusion and thermal conductivities.

The phase-change composition can further comprise a particulate filler, for example a filler to adjust the dielectric or magnetic properties of the phase-change composition. A low coefficient of expansion filler, such as glass beads, silica or ground micro-glass fibers, can be used. A thermally stable fiber, such as an aromatic polyamide, or a polyacrylonitrile can be used. Representative dielectric fillers include titanium dioxide (rutile and anatase), barium titanate, strontium titanate, fused amorphous silica, corundum, wollastonite, aramide fibers (e.g., KEVLAR™ from DuPont), fiberglass, Ba₂Ti₉O₂₀, quartz, aluminum nitride, silicon carbide, beryllia, alumina, magnesia, mica, talcs, nanoclays, aluminosilicates (natural and synthetic), iron oxide, CoFe₂O₄ (nanostructured powder available from Nanostructured & Amorphous Materials, Inc.), single wall or multiwall carbon nanotubes, and fumed silicon dioxide (e.g., Cab-O-Sil, available from Cabot Corporation), each of which can be used alone or in combination.

Other types of particulate fillers that can be used include an additional thermally insulating filler, a magnetic filler, or a combination thereof. Examples of thermally insulating fillers include, for example, organic polymers in particulate form. The magnetic fillers can be nanosized.

The fillers can be in the form of solid, porous, or hollow particles. The particle size of the filler affects a number of important properties including coefficient of thermal expansion, modulus, elongation, and flame resistance. In an embodiment, the filler has an average particle size of 0.1 to 15 micrometers, specifically 0.2 to 10 micrometers. The filler can be a nanoparticle, i.e., a nanofiller, having an average particle size of 1 to 100 nanometers (nm), or 5 to 90 nm, or 10 to 80 nm, or 20 to 60 nm. A combination of fillers having a bimodal, trimodal, or higher average particle size distribution can be used. The filler can be included in an amount of 0.5 to 60 weight percent, or 1 to 50 weight percent, or 5 to 40 weight percent, based on a total weight of the phase-change composition.

In addition, the phase-change composition can further optionally comprise an additive composition that includes one or more additives such as flame retardants, cure initiators, crosslinking agents, viscosity modifiers, wetting agents, antioxidants, thermal stabilizers, colorants, or the like. The particular choice of additives depends on the polymer and phase-change material used, the particular application of the phase-change composition, and the desired properties for that application. The additives in the additive composition are selected so as to enhance or not substantially adversely affect the properties of the phase-change composition, such as thermal conductivity, transition temperature, heat of fusion, or other desired properties.

The flame retardant can be a metal carbonate, a metal hydrate, a metal oxide, a halogenated organic compound, an organic phosphorus-containing compound, a nitrogen-containing compound, or a phosphinate salt. Representative flame retardant additives include bromine-, phosphorus-, and metal oxide-containing flame retardants. Suitable bromine-containing flame retardants are generally aromatic and contain at least two bromines per compound. Some that are commercially available are from, for example, Albemarle Corporation under trade names Saytex BT-93W (ethylenebistetrabromophthalimide), Saytex 120 (tetradecaboromodiphenoxybenzene), and Great Lake under trade name BC-52, BC-58, Esschem Inc under the trade name FR1025.

Suitable phosphorus-containing flame retardants include various organic phosphorous compounds, for example an aromatic phosphate of the formula (GO)₃P=O, wherein each G is independently an C₁₋₃₆ alkyl, cycloalkyl, aryl, alkylaryl, or arylalkyl group, provided that at least one G is an aromatic group. Two of the G groups can be joined together to provide a cyclic group, for example, diphenyl pentaerythritol diphosphate. Other suitable aromatic phosphates can be, for example, phenyl bis(dodecyl) phosphate, phenyl bis(neopentyl) phosphate, phenyl bis(3,5,5′-trimethylhexyl) phosphate, ethyl diphenyl phosphate, 2-ethylhexyl di(p-tolyl) phosphate, bis(2-ethylhexyl) p-tolyl phosphate, tritolyl phosphate, bis(2-ethylhexyl) phenyl phosphate, tri(nonylphenyl) phosphate, bis(dodecyl) p-tolyl phosphate, dibutyl phenyl phosphate, 2-chloroethyl diphenyl phosphate, p-tolyl bis(2,5,5′-trimethylhexyl) phosphate, 2-ethylhexyl diphenyl phosphate, or the like. A specific aromatic phosphate is one in which each G is aromatic, for example, triphenyl phosphate, tricresyl phosphate, isopropylated triphenyl phosphate, and the like. Examples of suitable di- or polyfunctional aromatic phosphorous-containing compounds include resorcinol tetraphenyl diphosphate (RDP), the bis (diphenyl) phosphate of hydroquinone, and the bis(diphenyl) phosphate of bisphenol-A, respectively, their oligomeric and polymeric counterparts, and the like.

Metal phosphinate salts can also be used. Examples of phosphinates are phosphinate salts such as for example alicyclic phosphinate salts and phosphinate esters. Further examples of phosphinates are diphosphinic acids, dimethylphosphinic acid, ethylmethylphosphinic acid, diethylphosphinic acid, and the salts of these acids, such as for example the aluminum salts and the zinc salts. Examples of phosphine oxides are isobutylbis(hydroxyalkyl) phosphine oxide and 1,4-diisobutylene-2,3,5,6-tetrahydroxy-1,4-diphosphine oxide or 1,4-diisobutylene-1,4-diphosphoryl-2,3,5,6-tetrahydroxycyclohexane. Further examples of phosphorous-containing compounds are NH1197® (Chemtura Corporation), NH1511® (Chemtura Corporation), NcendX P-30® (Albemarle), Hostaflam OP5500® (Clariant), Hostaflam OP910® (Clariant), EXOLIT 935 (Clariant), and Cyagard RF 1204®, Cyagard RF 1241® and Cyagard RF 1243R (Cyagard are products of Cytec Industries). In a particularly advantageous embodiment, a halogen-free phase-change composition has excellent flame retardance when used with EXOLIT 935 (an aluminum phosphinate). Still other flame retardants include melamine polyphosphate, melamine cyanurate, Melam, Melon, Melem, guanidines, phosphazanes, silazanes, DOPO (9,10-dihydro-9-oxa-10 phosphaphenanthrene-10-oxide), and 10-(2,5 dihydroxyphenyl)-10H-9-oxa-phosphaphenanthrene-10-oxide.

Suitable metal oxide flame retardants are magnesium hydroxide, aluminum hydroxide, zinc stannate, and boron oxide. Preferably, the flame retardant can be aluminum trihydroxide, magnesium hydroxide, antimony oxide, decabromodiphenyl oxide, decabromodiphenyl ethane, ethylene-bis (tetrabromophthalimide), melamine, zinc stannate, or boron oxide.

A flame retardant additive can be present in an amount known in the art for the particular type of additive used. In an embodiment the flame retardant type and amount is selected to provide a phase-change composition that can meet the UL94 V-2 standard.

Exemplary cure initiators include those useful in initiating cure (cross-linking) of the polymers, in the phase-change composition. Examples include, but are not limited to, azides, amine, peroxides, sulfur, and sulfur derivatives. Free radical initiators are especially desirable as cure initiators. Examples of free radical initiators include peroxides, hydroperoxides, and non-peroxide initiators such as 2,3-dimethyl-2,3-diphenyl butane. Examples of peroxide curing agents include dicumyl peroxide, alpha, alpha-di(t-butylperoxy)-m,p-diisopropylbenzene, 2,5-dimethyl-2,5-di(t-butylperoxy)hexane-3, and 2,5-dimethyl-2,5-di(t-butylperoxy)hexyne-3, and mixtures comprising one or more of the foregoing cure initiators. The cure initiator, when used, can be present in an amount of 0.01 weight percent to 5 weight percent, based on the total weight of the phase-change composition.

Crosslinking agents are reactive monomers or polymers. In an embodiment, such reactive monomers or polymers are capable of co-reacting with the polymer in the phase-change composition. Examples of suitable reactive monomers include styrene, divinyl benzene, vinyl toluene, triallylcyanurate, diallylphthalate, and multifunctional acrylate monomers (such as Sartomer compounds available from Sartomer Co.), among others, all of which are commercially available. Useful amounts of crosslinking agents are 0.1 to 50 weight percent, based on the total weight of the phase-change composition.

Exemplary antioxidants include radical scavengers and metal deactivators. A non-limiting example of a free radical scavenger is poly[[6-(1,1,3,3-tetramethylbutyl)amino-s-triazine-2,4-diyl][(2,2,6,6,-tetramethyl-4-piperidyl)imino]hexamethylene[(2,2,6,6-tetramethyl-4-piperidyl)imino]], commercially available from Ciba Chemicals under the tradename Chimassorb 944. A non-limiting example of a metal deactivator is 2,2-oxalyldiamido bis[ethyl 3-(3,5-di-t-butyl-4-hydroxyphenyl)propionate] commercially available from Chemtura Corporation under the tradename Naugard XL-1. A single antioxidant or a mixture of two or more antioxidants can be used. Antioxidants are typically present in amounts of up to 3 weight percent, such as 0.05 to 2.0 weight percent, 0.08 to 1.0 weight percent, or 0.1 to 0.5 weight percent, based on the total weight of the phase-change composition.

Coupling agents can be present to promote the formation of or participate in covalent bonds connecting a metal surface or filler surface with a polymer. Exemplary coupling agents include 3-mercaptopropylmethyldimethoxy silane and 3-mercaptopropyltrimethoxy silane and hexamethylenedisilazanes.

When an additive composition is present, e.g, a combination of a flame retardant, a cure initiator, a crosslinking agent, an antioxidant, and a thermal stabilizer, the phase-change composition can comprise 0.1 to 40 weight percent, 0.5 to 30 weight percent. 0.1 to 20, or 1 to 20 weight percent of the additive composition; wherein each weight percent is based on the total weight of the phase-change composition and totals 100 weight percent.

The phase-change composition can be manufactured by any suitable processing methods, including hot melt or solvent casting, hot melt extrusion and casting, compression molding, calendaring, roll over roll, knife over roll, reverse roll, slot die, gravure, or a combination thereof. Material can be process with or without solvent present. For example, the phase-change composition can be manufactured by combining the thermoplastic polymer composition, the phase-change material, optionally a solvent, the thermally conductive particles, and any additives to manufacture the phase-change composition. The combining can be by any suitable method, such as blending, mixing, or stirring. In an embodiment, the phase-change material is molten and the polymer, the thermally conductive particles, and optional additives are dissolved or dispersed in the molten phase-change material. In an embodiment, the components used to form the phase-change composition, including the polymer, the phase-change material, the thermally conductive particles, and the optional additives, can be combined by being dissolved or suspended in a solvent to provide a mixture or solution.

The solvent, when included, is selected so as to dissolve the polymer, disperse the phase-change material, thermally conductive particles, and any other optional additives that can be present, and to have a convenient evaporation rate for forming and drying. A non-exclusive list of possible solvents is xylene; toluene; methyl ethyl ketone; methyl isobutyl ketone; hexane, and higher liquid linear alkanes, such as heptane, octane, nonane, and the like; cyclohexane; isophorone; various terpene-based solvents; and blended solvents. Specific exemplary solvents include xylene, toluene, methyl ethyl ketone, methyl isobutyl ketone, and hexane, and still more specifically xylene and toluene. The concentration of the components of the composition in the solution or dispersion is not critical and will depend on the solubility of the components, the filler level used, the method of application, and other factors. In general, the solution comprises 10 to 80 weight percent solids (all components other than the solvent), more specifically 50 to 75 weight percent solids, based on the total weight of the solution.

Any solvent is allowed to evaporate under ambient conditions, or by forced or heated air, and the mixture is cooled to provide a gelled phase-change composition. The phase-change composition can also be shaped by known methods, for example extruding, molding, or casting. For example, the phase-change composition can be formed into a layer by casting onto a carrier from which it is later released, or alternatively onto a substrate such as a conductive metal layer that will later be formed into a layer of a circuit structure.

The layer can be uncured or partially cured (B-staged) in the drying process, or the layer can be partially or fully cured, if desired, after drying. The layer can be heated, for example at 20 to 200° C., specifically 30 to 150° C., more specifically 40 to 100° C. The resulting phase-change composition can be stored prior to use, for example lamination and cure, partially cured and then stored, or laminated and fully cured.

In another aspect, an article comprising the phase-change composition is disclosed. The phase-change composition can be used in a variety of applications, including electronic devices, LED devices, and circuit boards. The phase-change composition can be used with particular advantage in articles containing irregularly-shaped cavities that can be difficult to fill completely with solid PCM composites and materials. The phase-change composition can be used in a wide variety of electronic devices and any other devices that generate heat to the detriment of the performance of the processors and other operating circuits (memory, video chips, telecom chips, and the like). Examples of such electronic devices include cell phones, PDAs, smart-phones, tablets, laptop computers, hand-held scanners, and other generally portable devices. However, the phase-change composition can be incorporated into virtually any electronic device that requires thermal management during operation. For example, electronics used in consumer products, medical devices, automotive components, aircraft components, radar systems, guidance systems, and GPS devices incorporated into civilian and military equipment and other vehicles can benefit from aspects of the various embodiments, such as batteries, circuit boards, engine control units (ECU), airbag modules, body controllers, door modules, cruise control modules, instrument panels, climate control modules, anti-lock braking modules (ABS), transmission controllers, and power distribution modules. The phase-change composition and articles thereof can also be incorporated into the casings of electronics or other structural components. In general, any device that relies on the performance characteristics of an electronic processor or other electronic circuit can benefit from the increased or more stable performance characteristics resulting from utilizing aspects of the phase-change compositions disclosed herein.

The cavity of the article can be of any shape or size. The phase-change composition is especially useful for small cavities or cavities with intricate features, because such cavities can be readily filled using the phase-change compositions. The article can be, for example, an electronic device, preferably a hand-held electronic device.

An article comprising the phase-change composition can be manufactured by subjecting the phase-change composition to a temperature and/or pressure effective to result in flow properties permitting introduction of the phase-change composition into or onto a desired location of an article. In some embodiments, the effective temperature at atmospheric pressure is at least 100° C., or at least 110° C., or at least 120° C. to obtain a fluid phase-change composition and then introducing the fluid phase-change composition into or onto a location of an article.

Introducing the fluid phase-change composition into the cavity can be performed by gravity, for example pouring, injecting, or dropping. In a specific embodiment, introducing the fluid phase-change composition into the cavity can be performed by injecting.

In an aspect, the thermally conductive phase-change composition comprises in combination 5 to 25 weight percent of an elastomeric block copolymer, an elastomeric graft copolymer, an elastomeric random copolymer, or a combination thereof, preferably a styrenic block copolymer; 20 to 45 weight percent of a phase-change material that is alkane, a fatty acid, a fatty acid ester, a vegetable oil, or a combination thereof, and has a transition temperature of 10 to 95° C.; and 30 to 65 weight percent of thermally conductive particles, preferably where the thermally conductive particles comprise boron nitride, silica, alumina, zinc oxide, magnesium oxide, carbon fibers, graphite, aluminum nitride, or a combination thereof, and optionally 0.5 to 5 weight percent carbon fiber, wherein weight percent is based on the total weight of the composition and totals 100 weight percent. In this aspect, a thermal conductivity of the composition is at least 3.0 W/m-K at a temperature below a transition temperature of the phase-change material and thermal conductivity of the composition is at least 2.0 W/m-K at a temperature above the transition temperature of the phase-change material, wherein thermal conductivity is determined in accordance with ASTM E1530. Alternatively or in addition, the phase-change composition can have a heat of fusion, determined by differential scanning calorimetry according to ASTM D3418, of at least 85 Joules/gram; a transition temperature of 5 to 70° C. determined by differential scanning calorimetry according to ASTM D3418; or a combination thereof.

In another aspect, the thermally conductive phase-change composition comprises in combination 8 to 22 weight percent of an elastomeric block copolymer, an elastomeric graft copolymer, an elastomeric random copolymer, or a combination thereof, preferably a styrenic block copolymer; 20 to 40 weight percent of a phase-change material that is a paraffinic hydrocarbon, a fatty acid, or a fatty acid ester having 15 to 44 carbon atoms, 18 to 35 carbon atoms, or 18 to 28 carbon atoms, a vegetable oil, or a combination thereof, and having a transition temperature of 10 to 95° C.; and 35 to 60 weight percent of thermally conductive particles that comprise boron nitride, silica, alumina, zinc oxide, magnesium oxide, carbon fibers, graphite, aluminum nitride, or a combination thereof, and 0.5 to 5 weight percent carbon fiber, wherein weight percent is based on the total weight of the composition and totals 100 weight percent. In this aspect, a thermal conductivity of the composition is at least 3.0 W/m-K at a temperature below a transition temperature of the phase-change material and thermal conductivity of the composition is at least 2.0 W/m-K at a temperature above the transition temperature of the phase-change material, wherein thermal conductivity is determined in accordance with ASTM E1530. Alternatively or in addition, the phase-change composition can have a heat of fusion, determined by differential scanning calorimetry according to ASTM D3418, of at least 85 Joules/gram; a transition temperature of 5 to 70° C. determined by differential scanning calorimetry according to ASTM D3418; or a combination thereof.

The phase-change compositions described herein can provide improved thermal stability to a device, resulting in the ability to avoid degradation of performance and lifetime of electronic devices. The phase-change compositions are further advantageous for use as thermal management materials, especially in electronics, because they can easily be introduced into cavities of irregular shapes that can be difficult to fill completely with solid phase-change composition, permitting maximum heat absorption capacity.

The following examples are merely illustrative of the phase-change compositions and methods of manufacture disclosed herein and are not intended to limit the scope hereof.

### EXAMPLES

The heat of fusion of a sample is determined by differential scanning calorimetry (DSC), e.g., using a Perkin Elmer DSC 4000, or equivalent, according to ASTM D3418.

Thermal conductivity of a sample at a given temperature is determined in accordance with ASTM E1530 using, for example, a UNITHERM Model 2022 (ANTER Corp., Pittsburgh, PA), or equivalent.

Thermally conductive phase-change compositions are made according to the general formulation of Table 1 and then tested to determine properties of interest, including heat of fusion, thermal conductivity, and mechanical properties.

TABLE 1

Thermally conductive phase-change composition formulation

| Component | parts per hundred weight (PPH) |
|---|---|
| Linear styrene-ethylene/butylene-styrene (SEBS) tri-block copolymer, 10-25% polystyrene | 5-25 |
| Phase change material (PCM) of desired melting temperature | 20-45 |
| Thermally conductive particles | 30-65 |
| Optional carbon fibers | 0.5-5 |
| Optional antioxidant | 0 up to 0.5 |
| Total | 100 |

In these experiments, the compositions are made by hot melt processing or solvent casting. The linear SEBS, PCM, thermally conductive particles, optional carbon fibers, optional antioxidant, and optional solvent are mixed with heating until a homogenous phase-change composition is formed.

Formulations of representative compositions manufactured are provided in Table 2 below.

TABLE 2

Formulations of representative thermally conductive phase-change compositions

| Compositions: | Tc-1 | Tc-2 | Tc-3 | Tc-4 | Tc-5 | Tc-6 | 1 | 5 |
|---|---|---|---|---|---|---|---|---|
| Component | PPH | PPH | PPH | PPH | PPH | PPH | PPH | PPH |
| KRATON G1642 (Kraton Corporation) | 5.50 | 5.00 | | 5.50 | 10.00 | 10.00 | 11.05 | 5.50 |
| KRATON G1657 (Kraton Corporation) | 5.50 | 5.00 | 10.00 | 5.50 | | | | 5.50 |
| PCM 43P (Microtek Laboratories, Inc.) | 39.75 | 39.75 | 39.75 | 38.75 | | | 25.80 | 37.00 |
| PCM 43D (Microtek Laboratories, Inc.) | | | | | 39.75 | 39.75 | | |
| POLARTHERM PTX60 (Momentive Performance Materials, Inc.) | 35.00 | 35.00 | | 35.00 | 50.00 | | 22.10 | 38.00 |
| POLARTHERM PTX350 (Momentive Performance Materials, Inc.) | 13.00 | 15.00 | 40.00 | 13.00 | | 50.00 | 11.05 | 14.00 |
| GRANOC XN-100 05 M (Nippon Graphite Fiber Corp.) | 1.00 | | | 2.00 | | | | |
| GRANOC XN-100 03Z (Nippon Graphite Fiber Corp.) | | | 10.00 | | | | | |
| IRGANOX 1076 (BASF) | 0.25 | 0.25 | 0.25 | 0.25 | 0.25 | 0.25 | | |
| Toluene (not present in final composition) | | | | | | | 30.00 | |

DSC is performed on samples of the compositions to determine the heat of fusion. Thermal conductivity is also measured above and below the transition temperature. Results are shown in Table 3.

TABLE 3

Heat of fusion and thermal conductivity of phase-change compositions

| Composition | Heat of Fusion* (J/g) | Thermal Conductivity** (W/m-K) at RT (25° C.) | Thermal Conductivity** (W/m-K) at 60° C. |
|---|---|---|---|
| Sample 5 | 90 | 6.6 | n.d.# |
| Sample Tc-1 | 97 | 3.7 | 2.1 |
| Sample Tc-4 | 94 | 4.9 | 2.2 |

* ASTM D3418
**ASTM E1530
#n.d.=not determined

Compositions Tc-1 and Tc-4, including a small percentage of milled carbon fiber (1 or 2 weight percent, respectively), are observed to have decreased brittleness, increased mechanical strength, and increased softness compared to the other compositions lacking carbon fibers.

The claims are further illustrated by the following aspects, which are non-limiting.

Aspect 1: A phase-change composition comprising a mixture of 5 to 25 weight percent thermoplastic polymer; 20 to 45 weight percent phase-change material; and 30 to 65 weight percent thermally conductive particles, wherein weight percent is based on the total weight of the composition and totals 100 weight percent, and wherein thermal conductivity of the composition is at least 3.0 W/m-K at a temperature below a transition temperature of the phase-change material and thermal conductivity of the composition is at least 2.0 W/m-K at a temperature above the transition temperature of the phase-change material, wherein thermal conductivity is determined in accordance with ASTM E1530.

Aspect 2: The phase-change composition of aspect 1, wherein the thermoplastic polymer comprises an elastomeric block copolymer, an elastomeric graft copolymer, an elastomeric random copolymer, or a combination thereof.

Aspect 3: The phase-change composition of any one of the preceding aspects, wherein the thermoplastic polymer comprises a styrenic block copolymer.

Aspect 4: The phase-change composition of any one of the preceding aspects, wherein the phase-change material comprises an alkane, a fatty acid, a fatty acid ester, a vegetable oil, or a combination thereof.

Aspect 5: The phase-change composition of any one of the preceding claims, wherein the transition temperature of the phase-change material is 10 to 95° C.

Aspect 6: The phase-change composition of any one of the preceding aspects, wherein the thermally conductive particles comprise boron nitride, silica, alumina, zinc oxide, magnesium oxide, carbon fibers, graphite, aluminum nitride, or a combination thereof.

Aspect 7: The phase-change composition of any one of the preceding aspects, further comprising 0.5 to 5 weight percent carbon fiber, wherein weight percent is based on the total weight of the composition and totals 100 weight percent.

Aspect 8: The phase-change composition of any one of the preceding aspects, further comprising an additive composition, wherein the additive composition comprises a flame retardant, a thermal stabilizer, an antioxidant, a thermally insulating filler, a magnetic filler, a colorant, or a combination thereof.

Aspect 9: The phase-change composition of any one of the preceding aspects, further comprising a flame retardant, wherein the flame retardant comprises a metal carbonate, a metal hydrate, a metal oxide, a halogenated organic compound, an organic phosphorus-containing compound, a nitrogen-containing compound, a phosphinate salt, or a combination thereof.

Aspect 10: The phase-change composition of any one of the preceding aspects, having a heat of fusion, determined by differential scanning calorimetry according to ASTM D3418, at the transition temperature of at least 85 Joules/gram; a transition temperature of 5 to 70° C. determined by differential scanning calorimetry according to ASTM D3418; or a combination thereof.

Aspect 11: A method of manufacturing the phase-change composition of any one of the preceding aspects, the method comprising: combining the thermoplastic polymer composition, optionally a solvent, the phase-change material, and the thermally conductive particles to obtain a phase-change composition; and optionally removing the solvent.

Aspect 12: The method of clam 11, comprising hot melt processing, solvent casting, compression molding, calendaring, roll over roll processing, knife over roll processing, reverse roll processing, slot die processing, gravure processing, or a combination thereof.

Aspect 13: An article comprising the phase-change composition of any one of aspects 1 to 9 or manufactured by the method of aspect 11 or 12.

Aspect 14: The article of aspect 13, wherein the article is an electronic device, an LED device, or a printed circuit board.

Aspect 15: A method of manufacturing an article comprising a phase-change composition, the method comprising subjecting the phase-change composition of any one of aspects 1 to 10 or the phase-change composition manufactured by the method of aspect 11 or 12 to a temperature and/or pressure effective to introduce the phase-change composition into or onto a desired location of an article.

Aspect 16: The method of aspect 15, further comprising cooling the introduced phase-change composition.

Aspect 17: The method of aspect 15 or 16, wherein the article is an electronic device, an LED device, or a printed circuit board.

In general, the articles and methods described here can alternatively comprise, consist of, or consist essentially of, any components or steps herein disclosed. The articles and methods can additionally, or alternatively, be manufactured or conducted so as to be devoid, or substantially free, of any ingredients, steps, or components not necessary to the achievement of the function or objectives of the present claims.

The singular forms “a,” “an,” and “the” include plural referents unless the context clearly dictates otherwise. “Or” means “and/or.” Unless defined otherwise, technical and scientific terms used herein have the same meaning as is commonly understood by one of skill in the art to which the claims belong. A “combination” is inclusive of blends, mixtures, alloys, reaction products, and the like. The values described herein are inclusive of an acceptable error range for the particular value as determined by one of ordinary skill in the art, which will depend in part on how the value is measured or determined, i.e., the limitations of the measurement system. The endpoints of all ranges directed to the same component or property are inclusive of the endpoints and intermediate values, and independently combinable. In a list of alternatively useable species, “a combination thereof” means that the combination can include a combination of at least one element of the list with one or more like elements not named. Also, “at least one of” means that the list is inclusive of each element individually, as well as combinations of two or more elements of the list, and combinations of at least one element of the list with like elements not named.

Unless specified otherwise herein, all test standards are the most recent standard in effect as of the filing date of this application, or, if priority is claimed, the filing date of the earliest priority application in which the test standard appears. Unless defined otherwise, technical and scientific terms used herein have the same meaning as is commonly understood by one of skill in the art to which this disclosure belongs.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While the disclosed subject matter is described herein in terms of some embodiments and representative examples, those skilled in the art will recognize that various modifications and improvements can be made to the disclosed subject matter without departing from the scope thereof. Additional features known in the art likewise can be incorporated. Moreover, although individual features of some embodiments of the disclosed subject matter can be discussed herein and not in other embodiments, it should be apparent that individual features of some embodiments can be combined with one or more features of another embodiment or features from a plurality of embodiments.

1. A thermally conductive phase-change composition, comprising in combination:
5 to 25 weight percent of a thermoplastic polymer;
20 to 45 weight percent of a phase-change material; and
30 to 65 weight percent of thermally conductive particles,
wherein weight percent is based on the total weight of the composition and totals 100 weight percent, and
wherein thermal conductivity of the composition is at least 3.0 W/m-K at a temperature below a transition temperature of the phase-change material and thermal conductivity of the composition is at least 2.0 W/m-K at a temperature above the transition temperature of the phase-change material, wherein thermal conductivity is determined in accordance with ASTM E1530.

2. The phase-change composition of claim 1, wherein the thermoplastic polymer comprises an elastomeric block copolymer, an elastomeric graft copolymer, an elastomeric random copolymer, or a combination thereof.

3. The phase-change composition of claim 1, wherein the thermoplastic polymer comprises a styrenic block copolymer.

4. The phase-change composition of claim 1, wherein the phase-change material comprises an alkane, a fatty acid, a fatty acid ester, a vegetable oil, or a combination thereof.

5. The phase-change composition of claim 1, wherein the transition temperature of the phase-change material is 10 to 95° C.

6. The phase-change composition of claim 1, wherein the thermally conductive particles comprise boron nitride, silica, alumina, zinc oxide, magnesium oxide, carbon fibers, graphite, aluminum nitride, or a combination thereof.

7. The phase-change composition of claim 1, further comprising 0.5 to 5 weight percent carbon fiber, wherein weight percent is based on the total weight of the composition and totals 100 weight percent.

8. The phase-change composition of claim 1, further comprising an additive composition, wherein the additive composition comprises a flame retardant, a thermal stabilizer, an antioxidant, a thermally insulating filler, a magnetic filler, a colorant, or a combination thereof.

9. The phase-change composition of claim 1, further comprising a flame retardant, wherein the flame retardant comprises a metal carbonate, a metal hydrate, a metal oxide, a halogenated organic compound, an organic phosphorus-containing compound, a nitrogen-containing compound, a phosphinate salt, or a combination thereof.

10. The phase-change composition of claim 1, having a heat of fusion, determined by differential scanning calorimetry according to ASTM D3418, of at least 85 Joules/gram; a transition temperature of 5 to 70° C. determined by differential scanning calorimetry according to ASTM D3418; or a combination thereof.

11. A method of manufacturing the phase-change composition of claim 1, the method comprising:
combining to obtain a phase-change composition:
the thermoplastic polymer composition,
optionally a solvent,
the phase-change material, and
the thermally conductive particles; and
optionally removing the solvent.

12. The method of claim 11, comprising hot melt processing, solvent casting, compression molding, calendaring, roll over roll processing, knife over roll processing, reverse roll processing, slot die processing, gravure processing, or a combination thereof.

13. An article comprising the phase-change composition of claim 1.

14. The article of claim 13, wherein the article is an electronic device, an LED device, or a circuit board.

15. A method of manufacturing an article comprising a phase-change composition, the method comprising
subjecting the phase-change composition of claim 1 to a temperature and/or pressure effective to introduce the phase-change composition into or onto a desired location of an article.

16. The method of claim 15, further comprising cooling the introduced phase-change composition.

17. The method of claim 15, wherein the article is an electronic device, an LED device, or a circuit board.
